(19) United States
(12) Patent Application Publication
(10) Pub. No.: US 2018/0019334 A1
(43) Pub. Date: Jan. 18, 2018

(54) MULTILAYER PASSIVATION OF THE UPPER FACE OF THE STACK OF SEMICONDUCTOR MATERIALS OF A FIELD-EFFECT TRANSISTOR

(71) Applicants: THALES, COURBEVOIE (FR); COMMISSARIAT A L'ENERGIE ATOMIQUE ET AUX ENERGIES ALTERNATIVES (CEA), PARIS (FR)

(72) Inventors: Raphaël AUBRY, PALAISEAU (FR); Jean-Claude JACQUET, PALAISEAU (FR); Olivier PATARD, PALAISEAU (FR); Nicolas MICHEL, PALAISEAU (FR); Mourad OUALLI, PALAISEAU (FR); Sylvain DELAGE, PALAISEAU (FR)

(21) Appl. No.: 15/540,993

(22) PCT Filed: Dec. 29, 2015
(86) PCT No.: PCT/EP2015/081346

§ 371 Date: Jun. 29, 2017

(30) Foreign Application Priority Data
Dec. 30, 2014 (FR) 1403025

(51) Int. Cl. H01L 29/778; H01L 23/29; H01L 29/20; H01L 23/31

(52) U.S. Cl. CPC H01L 29/7787; H01L 29/2003; H01L 23/291; H01L 23/3171

(57) ABSTRACT

A field-effect transistor comprising a stack of semiconductor materials, the upper face of the stack being covered with a passivation layer comprises two sub-layers: a first sub-layer extending over a second zone of low intensity comprising a first material with electric breakdown field Ecl1, the charge of the first sub-layer being strictly less than the charge of the upper face of the stack, a second sub-layer extending over a first zone of high intensity and covering the first sub-layer, the second sub-layer comprising a second material with electrical breakdown field Ecl2 strictly greater than Ecl1.

The present invention concerns field-effect transistors of the high electron mobility transistor (HEMT) type.

The present invention concerns more precisely the stacks from which are fabricated HEMT used as a low-noise amplifier or power amplifier, as a switch or as an oscillator and covering the range of frequencies typically between 1 MHz and 100 GHz inclusive. And more particularly the layer protecting the upper face of the stack known as the “passivation layer”.

By “passivation layer” is meant a layer of material disposed on the upper face of the stack intended to protect the component against corrosion, mechanical wear, chemical attacks and to condition the states of surface electrical charges.

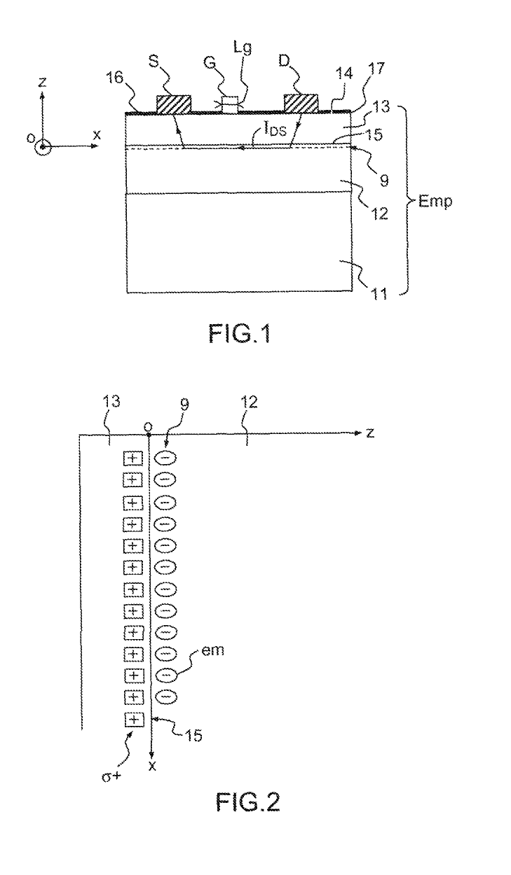

FIG. 1 shows a sectional view on a plane xOz of the structure of a classic elementary HEMT system produced on a substrate 11. There is conventionally used an insulative or semiconductor substrate 11 comprising for example silicon (Si), silicon carbide (SiC) or sapphire (Al₂O₃), on which is produced a stack Emp of at least two semiconductor layers that extend along the axis z in the plane xOy.

A first or buffer layer 12 has a wide forbidden band gap and consists of what is known as a wide gap semiconductor material. The buffer layer 12 comprises for example a material comprising a binary nitrogen compound such as GaN or a ternary nitride compound of group III elements, termed III-N, such as AlGaN, or to be more precise AlₓGa₁₋ₓN. The thickness of the buffer layer 12 along the axis z is typically between 0.2 μm and 3 μm inclusive.

A second layer 13 termed the barrier layer has a forbidden band gap wider than that of the buffer layer 12.

This barrier layer 13 comprises a material based on a quaternary, ternary or binary nitride compound of elements III, termed III-N, based on Al, Ga, In or B. The thickness of the barrier layer 13 is typically between 5 nm and 40 nm inclusive.

For example, with a GaN buffer layer 12 the barrier layer 13 may comprise AlₓGa₁₋ₓN or In₁₋ₓAlₓN or a sequence In₁₋ₓAlₓN/AlN or AlₓGa₁₋ₓN/AlN. Depending on the content x of aluminum, the widths of the forbidden band gap of AlₓGa₁₋ₓN and In₁₋ₓAlₓN vary between 3.4 eV (GaN) and 6.2 eV (AlN) and between 0.7 eV (InN) and 6.2 eV (AlN), respectively. There may be cited by way of example a GaN-based buffer layer 12 with a barrier layer based on AlGaN or InAlN, and to be more precise based on AlₓGa₁₋ₓN or In_{z}Al_{1-z}N, with x typically between 15% and 35% inclusive and z typically between 15% and 25% inclusive.

The buffer layer 12 and the barrier layer 13 are conventionally produced by metalorganic vapor phase epitaxy (MOCVD) or by molecular beam epitaxy (MBE).

Additional layers may be present on the upper face 14 of the stack Emp, notably a passivation layer 16.

The junction between the buffer layer 12 and the barrier layer 13 constitutes a heterojunction 15 that also extends in the plane xOy, the origin O of the system of axes (O, x, y, z) being chosen in that plane.

A HEMT conventionally comprises a source S, a drain D and a gate G deposited on the upper face 14 of the stack Emp. A gate G is disposed between the source S and the drain D and is used to control the transistor.

The conductance between the source S and the drain D is modulated by the electrostatic action of the gate G, typically of Schottky or MIS (metal/insulator/semiconductor) type and the voltage V_{GS} applied between the gate G and the source S controls the transistor.

A two-dimensional electron gas (2DEG) 9 is located in the vicinity of the heterojunction 15. These electrons are mobile in the plane xOy and have a high electron mobility μe; the electron mobility μe is typically greater than 1000 cm²/Vs.

In normal operation of the transistor these electrons cannot flow in the direction z because they are confined in the potential well formed in the plane xOy in the vicinity of the heterojunction 15. The electron gas 9 confined in what is referred to as the channel of the transistor is therefore able to transport a current I_{DS} flowing between the drain D and the source S.

A potential difference V_{DS} is conventionally applied between the source S and the drain D, typically with a grounded source S, and the value of the current I_{DS} is a function of the voltage V_{GS} applied between the gate G and the source S.

The transistor effect is based on the modulation of the conductance gm between the contacts of the source S and of the drain D by the electrostatic action of the control electrode G. The variation of this conductance is proportional to the number of free carriers in the channel and therefore to the current between the source S and the drain D.

It is the transistor amplification effect that makes it possible to transform a weak signal applied to the gate G into a stronger signal recovered at the drain D.

FIG. 2 shows the distribution of the electrical charges in the vicinity of the heterojunction 15.

Here the buffer layer 12 and the barrier layer 13 comprise strongly electronegative materials from the III-N family. Upon bringing two different compounds from this family into contact a fixed electrical charge appears at their interface that can be either positive σ+ as shown in FIG. 2 or negative σ−. This fixed charge attracts mobile charges: electrons when it is positive as in FIG. 2 or holes when it is negative. It is these mobile charges em that create a current when a voltage is applied between the drain D and the source S.

In fact, the HEMT structure comprising in particular a buffer layer 12 of GaN type has the particular feature of having the two-dimensional gas 9 close to the upper face 14 of the stack Emp, typically at a distance between 2 and 30 nm inclusive.

This two-dimensional gas 9 is generated by the equilibrium of the electrical charges in the stack Emp. It is therefore completely dependent on the electrical charges present on the upper face 14 of the stack Emp, and to be more precise on the electrical charges present at the interface 17 between the upper face 14 of the stack Emp and the passivation layer 16.

In other words, the two-dimensional gas 9 comprises electrical charges, here electrons, and these electrical charges are in part the image of the charges present on the surface of the stack Emp. Here, the two-dimensional gas 9 has a surface charge density of 10¹³ electrons·cm⁻² that also corresponds to the surface charge density of the upper face of the stack Emp.

Also, one function of the passivation layer 16 is to fix the surface state on the upper face 14 of the stack Emp, regardless of the conditions of use of the transistor, the voltage applied between the source S and the gate G, in a configuration minimizing the traps in the deep electrical centers so as to obtain a current close to the maximum current throughout the duration of operation of the transistor.

A deep center is an impurity the energy level of which is more than 2 to 3 times the thermal activation energy (3/2 k_{b}*T) of the minimum of the conduction band for a type N impurity or the maximum of the valency band for a P type impurity. At room temperature the thermal activation energy is of the order of 40 meV. A center will therefore be considered deep when situated at more than 100 meV from one of these extrema, which is the case for GaN doped with acceptor type impurities. These centers are negatively charged when the transistor is powered and as they are deep they are not discharged at operating frequencies above 1 megahertz. The effect of this is to reduce the number of mobile charges em present in the conductive channel, which reduces the current.

It follows that this approach also has the main disadvantage of generating dispersion, reducing the efficiency of the transistor and the power that it can output. This degraded performance increases as the operating voltage V_{DS} of the transistor increases, typically above 20 V.

At present the passivation layer 16 comprises a single layer of material, typically comprising silicon nitride (SiN) or silicon oxide (SiO₂) making it possible to reduce the effects of trapping at the interface 17 between the upper face 14 of the stack Emp and the passivation layer 16. This passivation protects the stack Emp of semiconductor materials for aggressive operating conditions such as high electric fields, greater than 6.10⁶ V/cm, and high operating temperatures, greater than 300° C.

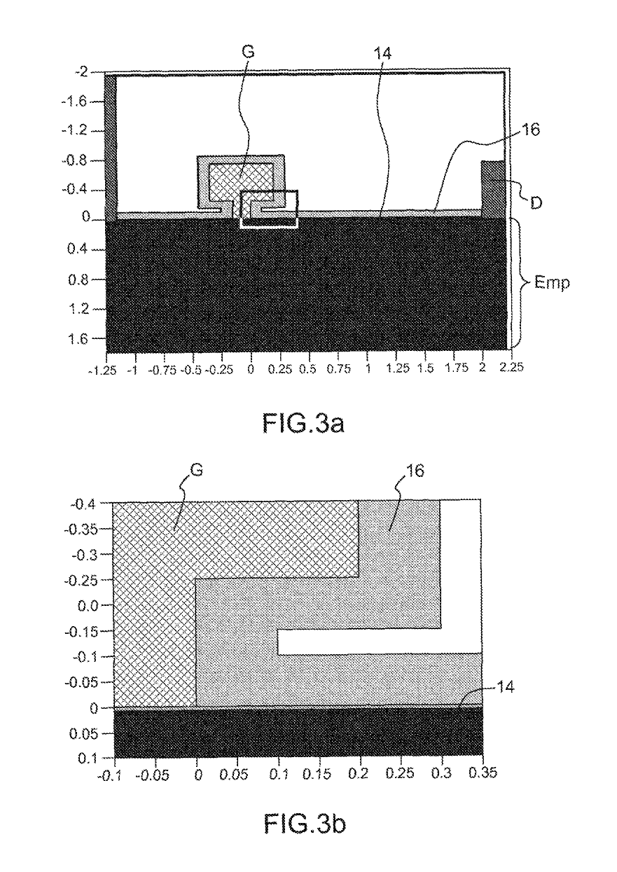

FIG. 3a shows a profile of a prior art transistor comprising a single passivation layer 16 on the surface of the upper face 14 of the stack Emp and FIG. 3b is a view to a larger scale of the base of the gate G also known as the gate base inside the box in FIG. 3a.

The upper face 14 of the stack comprises a source S, a gate G and a drain D.

Here, the upper face 14 of the stack Emp is covered with a continuous single passivation layer 16 according to the prior art typically comprising silicon nitride SiN.

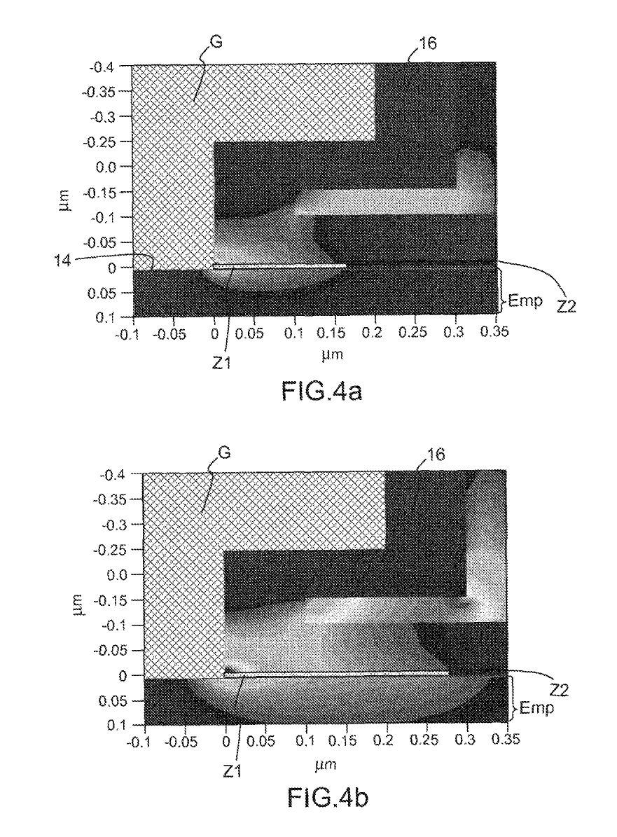

FIG. 4a corresponds to a mapping of the intensities of the electric field over the profile shown in FIG. 3b in the vicinity of the gate base G when a voltage V_{DS} of 20 V is applied and a drain current I_{DS} of 200 mA is measured per mm of gate length Lg. In other words, when the two-dimensional gas 9 flows.

Here, the values of the intensity of the electric field are represented by levels of grey, the zones in which the intensity of the electric fields is high are represented in light grey and the zones of lower electric field intensity are represented in dark grey. In other words, the higher the electric field intensity the lighter the zone concerned.

Here, two zones Z1; Z2 may be highlighted: a first zone Z1 of high electric field intensity disposed at the base of the gate G between the gate G and the drain D over a distance of approximately 0.15 μm from the base of the gate G, the intensity of the electric field over this first zone Z1 of high electrical intensity being between 3.75×10⁶ V·cm⁻¹ and 5×10⁶V·cm⁻¹, and a second zone Z2 of lower electric field intensity extending from the first zone Z1 of high intensity and extending over the rest of the upper face 14 over which the intensity of the electric field is less than 1×10⁶ V·cm⁻¹.

FIG. 4b is a mapping of FIG. 3b highlighting the intensity of the electric field when a negative bias is applied to the gate G preventing the two-dimensional gas 9 from flowing. Here, the electrical potential difference V_{GS} between the gate G and the source is −6 V. As in FIG. 4a it is also possible to distinguish a first zone Z1 and a second zone Z2 respectively of high and low electric field intensity.

The first zone Z1 of high intensity is more extensive than previously; it starts from the base of the gate G and extends over a distance of 0.25 μm. The part of the first zone Z1 of high intensity in direct contact with the gate G has an electric field intensity greater than 5×10⁶ V·cm⁻¹. The intensity of the electric field then decreases progressively in the distance away from the base of the gate G to reach values less than 2.5×10⁶ V·cm⁻¹ at a distance of 0.12 μm from the base of the gate G. The rest of the passivation layer 16 has electric field intensities less than 2.5×10⁶ V·cm⁻¹.

This first zone Z1 of high electric field intensity is also subject to a high temperature rise that can reach 400° C.

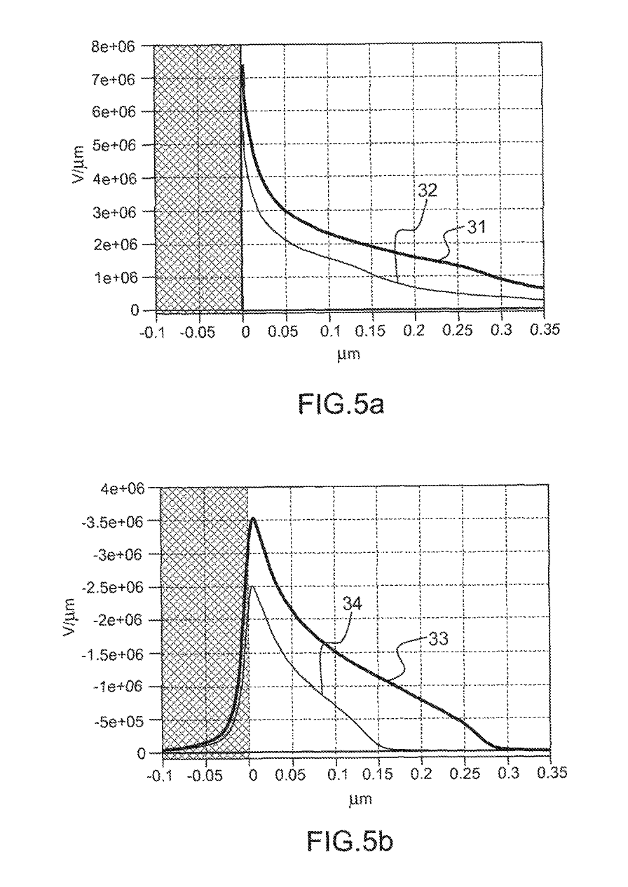

FIG. 5 are simulations of the evolution of the electric field as a function of the distance relative to the gate base G.

FIG. 5a shows simulated electric field intensity curves 31 and 32 as a function of the distance relative to the base of the gate at 5 nm from the surface of the stack Emp, i.e. inside the prior art single passivation layer, respectively for a pinched transistor not allowing the mobile charges of the two-dimensional gas 9 to flow and for an open transistor allowing the electrons to flow.

The curve 31 is a simulated graphical representation of the intensity of the electric field as a function of distance for a null voltage V_{DS} and a voltage V_{GS} equal to −5 V. In other words, it is a matter of the estimation of the electric field when the transistor is pinched, i.e. when the two-dimensional gas is depopulated under the gate. The intensity of the electric field (curve 31) decreases in the direction away from the gate G. It decreases rapidly in the vicinity of the gate base and then decreases more slowly. In fact, in contact with the gate G the intensity of the electric field is 7.2×10⁶ V/cm and the intensity is reduced by half at a distance of 0.025 μm relative to the gate base G. At a distance of 0.3 μm from the gate base the intensity of the electric field is only 10⁶ V/cm.

The curve 32 is a simulated graphical representation of the intensity of the electric field as a function of distance for a null voltage V_{DS} and a null voltage V_{GS}, the measured current I_{DS} being 200 mA/mm. In other words, the two-dimensional gas 9 flows in the channel. The curve 32 is similar to the curve 31. In contact with the gate base the intensity of the electric field is 5×10⁶V/cm and then decreases rapidly in the direction away from the gate base.

FIG. 5b shows the simulated curves 33 and 34 of intensity of the electric field as a function of the distance relative to the gate base G inside the channel.

The curve 33 is a simulated graphical representation of the intensity of the electric field inside the channel, i.e. in a plane buried in the stack, in contrast to the situations of the curves 31 and 32 in FIG. 5a. This simulation of the electric field is a function of the distance from the gate base G for a null voltage V_{DS} and a voltage V_{GS} equal to −5 V when the transistor is pinched.

The intensity of the electric field in the channel facing the gate base reaches a value of 3.5×10⁶ V/cm. This value is half the estimated value at the extreme surface (FIG. 5a). This value then decreases rapidly with distance.

In the same manner as previously, the curve 33 is an estimate of the electric field intensities in the channel when the two-dimensional gas flows. The intensity of the electric field in the channel facing the gate base reaches a value of 2.5×10⁶ V/cm.

These simulations show that the electric field intensities in the immediate vicinity of the gate base, i.e. over the first zone Z1, are very high and can reach 7×10⁶ V/cm and decrease very rapidly in the direction away from the gate base. The rest of the upper face 14 of the stack Emp constitutes the second zone Z2 of lower intensity.

These aggressive conditions of high electric field, greater than 7 MV/cm, high temperatures, greater than 350° C., can degrade the prior art passivation layer 16.

The surface state of the upper face 14 of the stack Emp can then be modified in particular by the hydroxide ions present in the surrounding atmosphere.

Therefore one object of the invention is to propose a passivation layer notably making it possible to improve the performance of the transistor.

According to one aspect of the invention there is proposed a field-effect transistor comprising:

a stack (Emp) of semiconductor materials along the axis z comprising a binary or ternary or quaternary nitride compound;

a drain (D), a source (S) and a gate (G);

a passivation layer (16) disposed on top of the upper face (14) of said stack (Emp), said passivation layer (16) comprising two sub-layers (16a; 16b); characterized in that said drain (D), said source (S) and said gate (G) define:

a first zone (Z1) of high electric field intensity at the base of the gate (G) between the gate (G) and the drain (D) or between the gate (G) and the source (S) when an electric voltage difference (V_{DS}, respectively V_{GS}) is applied between the drain (D) and the source (S) or between the gate (G) and the source (S), and

a second zone (Z2) of low electric field intensity; and in that:

said first sub-layer (16a) extends over the second zone (Z2), comprises a first material (Mat1) with an electric breakdown field E_{cl1}, the electrical charge of said first sub-layer (16a) being strictly less than the electrical charge of said upper face (14) of the stack (Emp),

said second sub-layer (16b) extends over the first zone (Z1), covers the first sub-layer (16a) and comprises a second material (Mat2) with an electric breakdown field E_{cl2} strictly greater than E_{cl1}.

The electric breakdown field of the second material Mat 2 is advantageously greater than the maximum electric field at the base of the gate base.

The synthesis temperature T_{synth} of the second material Mat2 is advantageously higher than the maximum temperature T_{Z1} reached over the first zone Z1 when the transistor is operating.

The charge of said first sub-layer 16a of the transistor is advantageously less than or equal to 1% of the charge of said upper face 14.

By synthesis temperature of the second material is meant the temperature reached when producing the material.

The production of a passivation layer comprising at least two sub-layers makes it possible to implement the functions of stabilization of the surface state and of protection of the surface of the stack against aggressive conditions of use such as a high electric field or high temperatures.

The residual charge density of the first material is advantageously less than or equal to 1% of the charge density per unit area of the upper face.

The thickness of the first sub-layer in the direction of the axis z is advantageously greater than or equal to 20 nm.

The first material advantageously comprises nitride of silicon (SiN) or alumina (Al₂O₃). The first material is preferably produced by induction coupled plasma chemical vapor phase deposition (ICP-CVD) or by atomic layer deposition (ALD).

This fabrication method enables deposition of silicon nitride atomic layer by atomic layer which enables production of a material of great purity, in particular depleted in oxygen, which limits the surface reactivity of the first sub-layer. The first sub-layer formed in this way is stable over time.

The second material advantageously comprises silicon nitride SiN or silicon oxide or aluminum nitride obtained by plasma-enhanced chemical vapor deposition (PECVD) or by cathode sputtering or by atomic layer deposition (ALD).

The above methods enable production of a material resistant to high electric fields, above the threshold value 10⁵V·cm⁻¹, and temperatures above 300° C.

The thickness of the second sub-layer in the direction of the axis z is advantageously greater than or equal to 50 nm so as to encapsulate the first sub-layer and to distance the surface of the first sub-layer from the surrounding atmosphere.

In accordance with another aspect of the invention there is proposed a method of fabricating a passivation layer on a stack of a transistor as claimed in any one of the preceding claims comprising:

a first step of synthesis of the first sub-layer comprising the first material on the second zone,

a second step of synthesis of the second sub-layer comprising the second material on the sub-layer and on the first zone.

The first material is advantageously synthesized by a method modifying only the first and second atomic layers of the upper face of the stack.

The first material is advantageously synthesized by induction coupled plasma chemical vapor phase deposition (ICP-CVD) or atomic layer deposition (ALD).

The synthesis temperature of the second material is advantageously higher than the maximum temperature observed over the first zone when the transistor is operating.

The second material is advantageously synthesized by a plasma-enhanced chemical vapor phase deposition (PECVD) method.

The invention will be better understood and other advantages will become apparent on reading the following description given by way of nonlimiting example and thanks to the appended figures, in which:

FIG. 1 already cited represents diagrammatically a section of the structure of a classic HEMT,

FIG. 2 already cited represents the distribution of the charges in the vicinity of the heterojunction of the classic HEMT,

FIG. 3a represents diagrammatically a profile of the stack Emp and FIG. 3b shows to a larger scale the boxed zone in FIG. 3a situated at the base of the gate,

FIGS. 4a and 4b are mappings of the electric field intensities at the base of the gate, respectively when the transistor is operating (curves 32 and 34) and when the transistor is pinched (curves 31 and 33),

FIGS. 5a and 5b represent simulated curves of the intensity of the electric field as a function of distance,

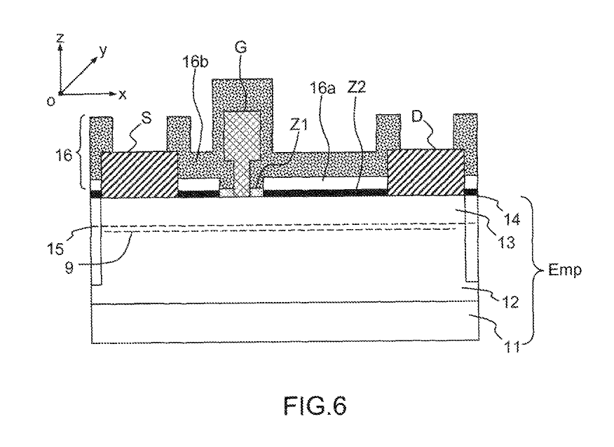

FIG. 6 is a diagrammatic representation of the passivation layer according to the invention,

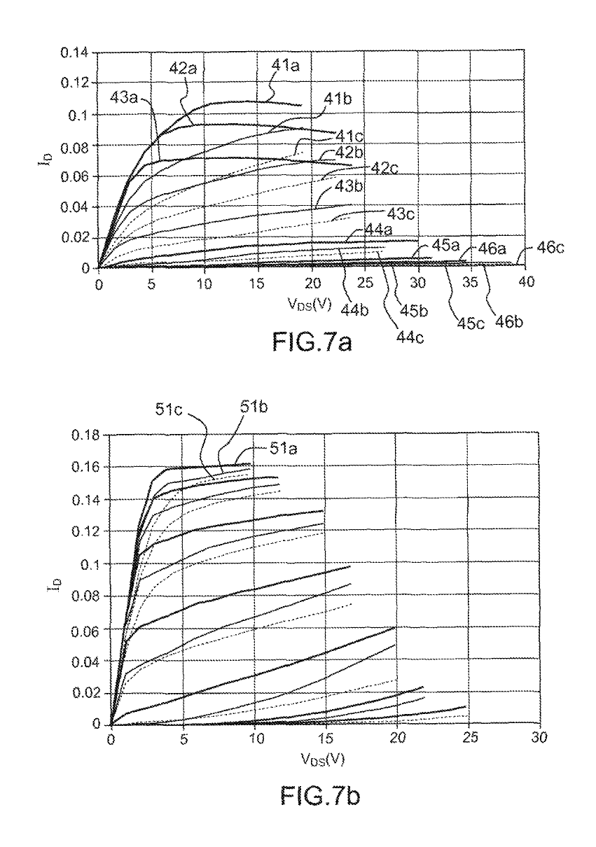

FIGS. 7a and 7b represent characterization curves of the transistors respectively with a prior art passivation layer and with a passivation layer according to the invention.

FIG. 6 is a diagrammatic representation of the profile of a stack comprising a passivation layer according to the invention.

The stack Emp comprises superposed layers of semiconductor materials. The stack Emp notably comprises a substrate 11, a buffer layer 12 and a barrier layer 13. On the upper face 14 of the stack Emp are disposed a source S, a gate G and a drain D. The upper face 14, the gate G, the source S and the drain D are covered with a passivation layer 16 according to the invention. Here, the barrier layer 13 may comprise InAlGaN, AlGaN or AlN. Now, the atoms of indium, gallium and nitrogen are particularly unstable and can easily react with the molecules of the surrounding atmosphere, which modifies the surface state of the upper face 14 of the stack Emp and consequently modifies the flow of the two-dimensional gas 9 in the channel. In fact, as already mentioned, the two-dimensional gas 9 is notably dependent on the surface state of the upper face 14 of the stack Emp.

The idea of the invention therefore consists in disposing a passivation layer on the surface of the upper face 14. The passivation layer 16 comprising two different materials so as to implement the two different functions of the passivation layer.

The passivation layer 16 comprises two sub-layers 16a; 16b: a first sub-layer 16a comprising a first material Mat 1 disposed on the second zone Z2 of the upper face 14 of the stack Emp intended to encapsulate the surface of the stack so as to fix the surface state and a second sub-layer 16b disposed on the first zone Z1 of the upper face 14 of the stack Emp and on the first sub-layer 16a, the second sub-layer 16b comprising a second material Mat 2 intended in particular to protect the upper face 14 of the stack from high electric field intensities.

Here the first material Mat 1 comprises silicon nitride SiN or nitride of Al₂O₃ produced by deposition methods such as atomic layer deposition (ALD).

This method notably enables the production of a deposit atomic layer by atomic layer enabling a dense and weakly reactive deposit of the first material Mat 1 to be produced. Nevertheless, the use of ALD does not imply the production of a dense and weakly reactive material: these characteristics can vary as a function of the deposition parameters, which are chosen in the embodiments of the invention to be suited to the production of a dense and weakly reactive material.

However, other so-called “soft” deposition methods enabling production of a dense and weakly reactive deposit can be envisaged such as induction coupled plasma chemical vapor deposition (ICP-CVD).

By soft deposition method is meant a method that modifies at most the extreme surface of the material on which the deposit is produced. The extreme surface typically corresponds to one or even two atomic layers. A soft deposition method preferably does not modify the surface of the material on which the deposit is produced.

The above methods generally do not include steps of electron or ion bombardment of the surface on which the deposit is produced. There may be cited by way of example a spin coating deposition method.

The sub-layer 16a produced in this way has an electrical charge (i.e. a charge per unit area) strictly less than the electrical charge of the upper face 14 of the stack Emp and to be more precise the electrical charge of the upper surface 14 in contact with said sub-layer 16a. The electrical charge of the sub-layer 16a is advantageously less than a few percent of the electrical charge of the two-dimensional gas 9 and to be more precise less than or equal to 10% thereof and preferably less than 1% thereof. The electrical charge of the two-dimensional gas 9 is a function of the electrical charge of the upper surface 14 and is substantially equal to the electrical charge of the upper surface 14. The charge of said first sub-layer is advantageously less than or equal to 10% of the charge of said upper face 14 and preferably less than or equal to 1% of the charge of said upper face 14. Accordingly, by treating the sub-layer 16a as similar to a surface, the surface charge density δₘₐₜ₁ of the sub-layer 16a is preferably between 10¹⁰ and 10¹² charges·cm⁻² inclusive.

The thickness of the first sub-layer 16a in the direction of the stack Emp is advantageously greater than 20 nm so as to fix the surface state of the upper face 14 of the stack Emp.

Here, the second sub-layer 16b comprises a second material Mat 2 resistant to high electric field intensities and to high temperatures above 200° C., the second sub-layer 16b being disposed on the first zone Z1 of high intensity and on the first sub-layer 16a.

The second material Mat2 advantageously comprises silicon nitride SiN, silicon oxide SiO₂ or aluminum nitride AlN produced by plasma-enhanced chemical vapor deposition (PECVD) or by cathode sputtering or by atomic layer deposition (ALD) and heat treatment. The parameters of an ALD deposit of a layer of material Mat2 are different from those potentially used for the deposition of a layer of the material Mat1.

These materials produced in this way are more resistant to high temperatures and to high electric field intensities. In the embodiments of the invention the breakdown electric field E_{cl2} of the second sub-layer 16b is strictly greater than the breakdown electric field E_{cl1} of the first sub-layer 16a. The methods of depositing the sub-layers 16 are chosen among other things to allow this inequality.

The thickness of the second sub-layer 16b above the first sub-layer 16a in the direction of the stack Emp is advantageously greater than 50 nm so as to distance the surface of the first sub-layer 16a from the surrounding atmosphere.

FIGS. 7a and 7b represent transistor characterization curves for different gate voltage values, respectively for a transistor comprising a prior art single passivation layer and a passivation layer according to the invention.

FIG. 7a represents the characteristic curves of transistors comprising a prior art single passivation layer. The pulsed measurements produced for different points of rest enable the charge effects to be quantified.

The thick line curves 41a; 42a; 43a; 44a; 45a, 46a and 47a represent the drain current I_{D} as a function of the pulsed voltage V_{DS} applied between the drain and the source for a quiescent point V_{GS}=0 V and V_{DS}=0 V and for different gate voltages from +1 V to −5 V.

These curves correspond to the nominal mode V_{GS}=0 V and V_{DS}=0 V when the transistor is used for the first time or in other words when no bias has been applied to the transistor beforehand.

The single line curves 41b; 42b; 43b; 44b; 45b; 46b and 47b represent the drain current I_{D} as a function of the voltage V_{DS} applied between the drain D and the source S for a quiescent point V_{GS}=−Vp and V_{DS}=0 V and for different gate voltages from +1 V to −5 V.

The dashed line curves 41c; 42c; 43c; 44c; 45c; 46c and 47c represent the drain current I_{D} as a function of the pulsed voltage applied between the drain D and the source S for a quiescent point V_{GS}=−Vp and V_{DS}=25 V for different gate voltages from +1 V to −5 V.

The conditions corresponding to the points of rest V_{GS}=−Vp and V_{DS}=0 V and V_{GS}=−Vp and V_{DS}=25 V are equivalent to the biasing conditions of the transistor when operating at microwave frequencies.

During the first use and for a gate voltage of +1 V (curve 41a), i.e. for a voltage allowing the electrons to pass, the current increases in a linear manner before reaching a plateau at a value of 1.1 A/mm. Following biasing V_{DS}=25 V and V_{GS}=−Vp (curve 41c) and for a gate voltage of +1 V the value of the current reaches the plateau at a value of 0.75 A/mm.

Here, a large drop in the maximum current is observed between the measurement of the drain current I_{D} of a transistor comprising a prior art single passivation layer: on the one hand during use with a quiescent point Vgs=0 and Vds=0 (curve 41a) and on the other hand during use with a quiescent point simulating a transistor operating at V_{GS}=−Vp and V_{DS}=25 V (curve 41c). This drop in current is estimated at approximately 37% and may be attributed to trapping of the electrons em in deep centers.

For the other sets of curves (42a; 42b; 42c) to (47a; 47b; 47c) there is also a reduction of the maximum drain current I_{D} between the curves 42a to 47a for a transistor used for the first time and the curves 42c to 47c simulating a transistor in operation.

Moreover, if the gate voltage V_{GS} falls to negative values with a higher absolute value, the maximum drain current I_{D} decreases. In fact, the gate voltage can be regarded as similar to a voltage of pinching of the channel or of closing of the channel. In other words, the more the absolute value of the gate voltage increases the less electrons flow in the channel and therefore the lower the drain current I_{D} until it reaches a value substantially equal to zero for a gate voltage equal to the pinch voltage. Here, the gate voltage V_{G} is −5 V.

FIG. 7b represents the characteristic curves of transistors comprising a multilayer passivation layer according to the invention.

The curves 51a; 52a; 53a; 54a; 55a; 56a and 57a represent the drain current I_{D} as a function of the pulsed voltage V_{DS} applied between the drain and the source for a quiescent point V_{GS}=0 V and V_{DS}=0 V and for different gate voltages from +1 V to −5 V.

The curves 51a; 52a; 53a; 54a; 55a; 56a and 57a correspond to the first use V_{GS}=0 V and V_{DS}=0 V when the transistor is used for the first time or in other words when no bias has been applied to the transistor beforehand.

The curves 51b; 52b; 53b; 54b; 55b; 56b and 57b represent the drain current as a function of the pulsed voltage applied between the drain and the source for a quiescent point V_{GS}=−Vp and V_{DS}=0 V for different gate voltages from +1 V to −5 V.

The curves 51c; 52c; 53c; 54c; 55c; 56c and 57c represent the drain current I_{D} as a function of the pulsed voltage V_{DS} applied between the drain and the source for a quiescent point V_{GS}=−Vp and V_{DS}=25 V for different gate voltages from +1 V to −5 V.

The conditions corresponding to the points of rest V_{GS}=−Vp and V_{DS}=0 V and V_{GS}=−Vp and V_{DS}=25 V are equivalent to the biasing conditions of the transistor when operating at microwave frequencies.

In nominal mode, i.e. during its first use with no previous biasing, and for a gate voltage of +1 V (curve 51a), i.e. for a gate voltage V_{GS} allowing the electrons to pass, the current increases in a linear manner before reaching a plateau at a value of 1.6 A/mm.

During the first use with no previous biasing the maximum drain current I_{D} of a transistor comprising a multilayer passivation layer according to the invention is higher than the drain current of a transistor comprising a prior art single passivation layer.

It can therefore be concluded that even in nominal mode some of the electrons em are trapped in the stack and that the use of a multilayer passivation layer 16 according to the invention enables the trapping of the electrons to be limited.

Moreover, with a quiescent point V_{GS}=Vp and V_{DS}=25 V and for a gate voltage of +1 V the value of the current I_{D} reaches a plateau at a value of 1.5 A/mm i.e. a current drop of approximately 7%.

The production of a passivation layer according to the invention therefore enables the surface state of the upper face of the stack to be fixed and thus the two-dimensional gas to be confined in the channel by avoiding the trapping of electrons in deep centers.

Moreover, the passivation layer according to the invention enables protection of the stack from high electric field intensities and high temperatures. The performance of a transistor comprising a passivation layer according to the invention is therefore improved.

1. A field-effect transistor comprising:
a stack of semiconductor materials along the axis z comprising a binary or ternary or quaternary nitride compound;
a drain, a source and a gate;
a passivation layer 464 disposed on top of the upper face of said stack, said passivation layer comprising two sub-layers; wherein said drain, said source and said gate define:
a first zone of high electric field intensity at the base of the gate between the gate and the drain or between the gate and the source when an electric voltage difference is applied between the drain and the source or between the gate and the source, and
a second zone of low electric field intensity;
and wherein:
said first sub-layer extends over the second zone, comprises a first material with an electric breakdown field E_{cl1}, the electrical charge of said first sub-layer being strictly less than the electrical charge of said upper face of the stack,
said second sub-layer extends over the first zone, covers the first sub-layer and comprises a second material with an electric breakdown field E_{cl2} strictly greater than E_{cl1}.

2. The transistor as claimed in claim 1 wherein the charge of said first sub-layer is less than or equal to 1% of the charge of said upper face.

3. The transistor as claimed in claim 1 wherein the thickness of the first sub-layer in the direction of the axis z is greater than or equal to 20 nm.

4. The transistor as claimed in claim 1 wherein the first material comprises silicon nitride or alumina.

5. The transistor as claimed in claim 4 wherein the first material is produced by induction coupled plasma chemical vapor phase deposition or by atomic layer deposition.

6. The transistor as claimed in claim 1 wherein the second material comprises silicon nitride or silicon oxide or aluminum nitride.

7. The transistor as claimed in claim 6 wherein the second material is obtained by plasma-enhanced chemical vapor phase deposition or by cathode sputtering or by atomic layer deposition with heat treatment.

8. The transistor as claimed in claim 1 wherein the thickness of the second sub-layer in the direction of the axis z is greater than or equal to 50 nm.

9. A method of fabricating a passivation layer on a stack of a transistor as claimed in claim 1 comprising:
a first step of synthesis of the first sub-layer comprising the first material on the second zone,
a second step of synthesis of the second sub-layer comprising the second material on the sub-layer and on the first zone.

10. The method as claimed in claim 9 wherein the first material is synthesized by a method modifying only the first and second atomic layers of the upper face of the stack.

11. The method as claimed in claim 10 wherein the first material is synthesized by induction coupled plasma chemical vapor phase deposition or atomic layer deposition.

12. The method as claimed in claim 9 wherein the synthesis temperature of the second material is higher than the maximum temperature observed over the first zone when the transistor is operating.

13. The method as claimed in claim 12 wherein the second material is synthesized by a plasma-enhanced chemical vapor phase deposition method or by cathode sputtering or by atomic layer deposition with heat treatment.
